(19) United States
(12) Patent Application Publication
(10) Pub. No.: US 2025/0149904 A1
(43) Pub. Date: May 8, 2025

(54) METHOD FOR CHARGING A RECHARGEABLE ENERGY STORAGE

(71) Applicant: BENNING CMS TECHNOLOGY GMBH, March (DE)

(72) Inventor: Walter WOLFRAM, Eschbach (DE)

(21) Appl. No.: 18/925,478

(22) Filed: Oct. 24, 2024

Related U.S. Application Data
(63) Continuation of application No. PCT/DE2023/100298, filed on Apr. 25, 2023.

(30) Foreign Application Priority Data
Apr. 25, 2022 (DE) DE102022109869.9

(51) Int. Cl. H02J 7/00; G01R 31/388; G01R 31/392; H01M 10/44

(52) U.S. Cl. CPC H02J 7/0013; G01R 31/388; G01R 31/392; H01M 10/441; H02J 7/00047; H02J 7/0048; H02J 7/005; H02J 7/00714

(57) ABSTRACT

A method for charging a rechargeable energy store with a charging current, wherein the energy store has at least one cell block having a number J of series-connected battery cells of which at least some having different capacitances Cn, where 1≤n≤J. Firstly, all J battery cells are charged with a charging current Io until a battery cell i reaches an end-of-charging voltage Ui,L that is specified for said battery cell i. Then, for all battery cells, the charging current is reduced to a value h. If the reduced charging current is less than a charging current threshold value, the charging current is shut off for all battery cells, and the battery cell m having the lowest cell voltage Umin and the battery cell I having the highest cell voltage Umax are determined.

### RELATED APPLICATIONS

This application is a continuation of international patent application PCT/DE2023/100298 filed on Apr. 25, 2023, claiming priority from German patent application DE 10 2022 869.9 filed on Apr. 25, 2022, both of which are incorporated in their entirety by this reference.

### FIELD OF THE INVENTION

The invention relates to a method for charging a rechargeable energy storage, the energy storage includes at least one cell block with a number J of series-connected battery cells.

### BACKGROUND OF THE INVENTION

A rechargeable energy storage including a plurality of galvanic cells connected in series and/or in parallel, referred to as battery cells. When these battery cells are discharged, the stored chemical energy is converted into electrical energy. This electrical energy can be used by an off-grid consumer, such as an electric vehicle. In addition, the electrical energy from the rechargeable energy storage can be used by a consumer that is connected to a power grid to bridge an interruption in the power supplied from the power grid. The rechargeable energy storage equipped with rechargeable battery cells is recharged after a discharge to be available for reuse.

In the case of rechargeable energy storages (accumulators) consisting of several rechargeable battery cells connected in series, it is important for the service life of the energy storage that each individual cell is neither overcharged when the rechargeable energy storage is charged, nor discharged too deeply when discharged, and that all cells have the same state of charge as far as possible. This applies in particular to rechargeable energy storages such as of several lithium-ion batteries, lithium-polymer batteries and/or lithium-iron-phosphate batteries connected in series.

When battery cells are connected in series, the same charging current flows through all of the battery cells. Because battery cells may have different internal resistances or efficiencies, the power dissipated by each battery cell during charging varies. This means that after charging, not all battery cells have the same capacity available for subsequent discharging. This capacity is also called usable capacity. The battery cell with the highest internal resistance or poorest efficiency has the lowest usable capacity after the cell block has been charged because it has the highest power dissipation. As a result, this cell will be discharged the furthest during the subsequent discharge. It is therefore the cell with the highest Depth of Discharge (DoD) in the cell block. However, the higher the DoD of a cell, the shorter the life of that cell. This leads to disproportionate aging of that one cell and thus to premature failure of the cell block.

To determine the respective state of charge of a battery cell, its respective cell voltage can be measured and then, if necessary, charge equalization can be performed between the battery cells of the cell block if the battery cells have different states of charge when the cell voltage exceeds or falls below certain cell voltage values. However, the problem is that the cell voltage remains largely constant, at least in sections, during the respective charging process of a battery cell, so that it is difficult to deduce the current state of charge of the corresponding battery cell from the cell voltage. Only shortly before the respective end-of-charge or end-of-discharge voltage is reached, there is a relatively sharp rise or fall in the respective cell voltage, which can be used for corresponding control processes for charge equalization. However, these equalization processes take a long time. During this time, the battery block cannot be used for normal operation.

Such rechargeable energy storages are therefore usually connected to a device, often referred to as a battery management system, which on the one hand constantly monitors the state of charge of the individual battery cells by means of a charge controller and on the other hand attempts to equalize them if the state of charge of the individual battery cells differs. The equalization of the state of charge of the battery cells, also known as balancing, can be achieved by passive or active balancing. In addition, with known battery management systems, charge equalization does not begin until at least one of the battery cells is fully charged, making the entire charging process of a cell block relatively time-consuming.

In passive equalization, the excess energy is converted to heat via a resistor in the battery cell that has reached its end-of-charge voltage first and is therefore lost to the charging process.

In active balancing, the energy extracted from a cell with too high voltage is not converted into thermal energy, but is used to charge the other cells in the rechargeable energy storage. However, even with active balancing, charge equalization does not begin until at least one of the battery cells in the cell block has reached its end-of-charge voltage.

DE 10 2017 009 850 A1 discloses a method for charging and discharging a rechargeable energy storage with at least one cell block including several battery cells connected in series without active or passive balancing. In this known method, all battery cells reach their end-of-charge voltage or end-of-discharge voltage simultaneously. For this purpose, the characteristic maximum charging current I_{N;max} is determined from the capacity C_{N} of each battery cell, taking into account a predetermined C-factor which corresponds to the quotient of the maximum charging current I_{N;max} and the capacity C_{N} of each of the battery cells. During a predetermined time t, which is less than or equal to the reciprocal of the C-factor, all the battery cells are charged simultaneously with the maximum charging currents I_{N;max} assigned to them. The difference between the available charging current I₀ and the maximum charging current I_{N;max} of a battery cell is taken from or supplied to the cell block as auxiliary charging current via auxiliary charging/discharging devices. Discharge takes place accordingly.

DE 10 2019 129 415 B3 discloses a method for charging and/or discharging a rechargeable energy storage with a current I₀, wherein the rechargeable energy storage includes at least one cell block with a number J of battery cells connected in series and at least some of the battery cells have different efficiencies nu with 1≤N≤J. The battery cell with the worst efficiency ηₘᵢₙ is determined first. The efficiencies η_{N} of all other battery cells are then adjusted to this worst efficiency ηₘᵢₙ such that the adjusted efficiency η_{N′} of the battery cells is: η_{N′}=ηₘᵢₙ.

### BRIEF SUMMARY OF THE INVENTION

The object of the invention is to provide a method for charging and discharging a rechargeable energy storage with battery cells connected in series without active or passive balancing, in which all battery cells are charged simultaneously and all battery cells have their predetermined end-of-charge voltage at the end of the charging process, in particular even if individual battery cells have different charge states, capacities, internal resistances, efficiencies or states of health, whereby auxiliary charging currents and auxiliary discharging currents as well as active equalization of the efficiencies of the battery cells can be dispensed with. This object is achieved by a method for charging a rechargeable energy storage including a rechargeable energy storage with a charging current, wherein the rechargeable energy storage includes at least one cell block including a number J of series-connected battery cells. At least some of the battery cells have different capacities Cₙ, different internal resistances and/or different efficiencies, wherein 1≤n≤ J. The method includes a) charging all J battery cells with a charging current I₀, b) recording cell voltage Uₙ of all J battery cells wherein the recording is carried out continuously or at predetermined time intervals, c) comparing the recorded cell voltage Uₙ of each battery cell with the predetermined end-of-charge voltage U_{n,L} specified for this battery cell, d) as soon as a battery cell i with 1≤i≤J reaches a predetermined end-of-charge voltage U_{i,L} for this battery cell i, the charging current for all battery cells is reduced to a value Iᵢ for which the following applies 0A<Iᵢ<I₀, whereby Iᵢ is a predetermined charging current for this battery cell i at which the cell voltage Uᵢ of battery cell i does not rise above the end-of-charge voltage U_{i,L}, while all battery cells continue to be charged with the charging current Iᵢ, e) as soon as during charging of the battery cells with the charging current Iᵢ, another battery cell j reaches its predetermined end-of-charge voltage, the charging current is further reduced to a charging current Iⱼ with 1≤j≤J and j≠i and Iᵢ<Iᵢ, f) as soon as the reduced charging current Iᵢ or Iⱼ is less than a specified charging current threshold value I_{SW}, the charging current is switched off for all battery cells and the cell voltage Uₙ is determined for each battery cell with 1≤n≤J, g) the battery cell m with the lowest cell voltage Uₘ=Uₘᵢₙ is determined and the battery cell I with the highest cell voltage U_{I}=Uₘₐₓ is determined, h) with exception of the battery cell m, all other battery cells are discharged via resistors which are connected in parallel with the battery cells until for the cell voltage U_{I} the following applies: U_{I}=Uₘᵢₙ, wherein the steps a) to h) are repeated in cycles until the difference Uₘₐₓ−Uₘᵢₙ is less than or equal to a predetermined limit value Δ_{U1} and Uₘₐₓ−Uₘᵢₙ≤Δ_{U1} applies.

The method is characterized by a rechargeable energy storage comprising at least one cell block with a number J of series-connected battery cells which may have different capacities Cₙ, different internal resistances and/or different efficiencies, where 1≤n≤J, whereby all J battery cells are charged with a charging current I₀ until a battery cell i, where 1≤i≤J, reaches an end-of-charge voltage U_{i,L} which is predetermined for this battery cell i. The charging current is then reduced for all battery cells to a value Iᵢ for which the following applies 0A<Iᵢ<I₀. Iᵢ is a predetermined charging current for this battery cell i at which the cell voltage Uᵢ of the battery cell i does not rise above the end-of-charge voltage U_{i,L} of this battery cell i, while all battery cells continue to be charged with the charging current Iᵢ.

All reduced charging currents Iᵢ do not result in an increase in the cell voltage U_{i,L} of battery cell i. Nevertheless, the charging current Iᵢ ensures that the remaining battery cells in the cell block continue to be charged and their cell voltage continues to increase.

The cell voltage of all J battery cells is measured continuously or at specific times during the charge. For each battery cell, the recorded cell voltage is periodically compared with the end-of-charge voltage predetermined for the battery cell. For example, the cell voltage can be determined at regular intervals. In addition, the cell voltage can be determined whenever one of the battery cells reaches its predetermined end-of-charge voltage.

As soon as charging a battery cell i reaches its end-of-charge voltage, the charging current is reduced from I₀ to Iᵢ. The charging is switched from constant current CC to constant cell voltage CCV so that the cell voltage Uᵢ in this battery cell i does not increase any further. In all other battery cells, charging with the reduced charging current Iᵢ will result in an increase in the cell voltage Uₙ with 1≤n≤J and n≠i and an increase in the state of charge.

The charging current Iᵢ is reduced to a charging current Iⱼ with 1≤j≤J and j≠i and Iᵢ<Iᵢ, when during charging the battery cells with the charging current Iᵢ another battery cell j reaches its predetermined end-of-charge voltage before charging is completed. This applies to the battery cell which is the next to reach its predetermined end-of-charge voltage after battery cell i, and also to each additional battery cell which reaches its end-of-charge voltage thereafter, as long as charging continues. Charging is terminated only when the reduced charging current is less than a specified charging current threshold value I_{SW}.

Since the charging current is reduced from I₀ to Iᵢ when the battery cell i has reached its predetermined end-of-charge voltage U_{i,L} and the charging current Iᵢ is less than I₀, during the first charging of a cell block after charging according to the invention, it may take some time for all battery cells to reach their predetermined end-of-charge voltage. Since all battery cells start at their predetermined end-of-charge voltage during subsequent discharging, the battery cells are not discharged to a DoD that leads to disproportionate aging and premature failure of the cell block. It is assumed that in all further charging processes of this cell block the battery cells will reach their predetermined end-of-charge voltage almost simultaneously or shortly one after the other, so that rapid charging will take place in the further charging processes.

The method according to the invention differs from known methods in which the entire block of cells is charged to a block end-of-charge voltage. This block end-of-charge voltage is generally significantly lower than an end-of-charge voltage resulting from the sum of the individual end-of-charge voltages of all cells. In the method according to the invention, the cell block is charged until all battery cells of the cell block have reached a predetermined end-of-charge voltage for them, taking into account a tolerance which is small compared to the predetermined end-of-charge voltage of the cells. The predetermined end-of-charge voltage for the J battery cells in the cell block may be the same for all the battery cells. However, it is also possible to specify different end-of-charge voltages for different battery cells. Again, the end-of-charge voltage of the cell block is the sum of the end-of-charge voltages of the individual battery cells.

The charging current is switched off for all battery cells if the reduced charging current Iᵢ or Iᵢ is less than a predetermined charging current threshold value I_{SW}. Then the cell voltage Uₙ is determined for each battery cell with 1≤n≤J. Then the battery cell m with the lowest cell voltage Uₘ=Uₘᵢₙ and the battery cell I with the highest cell voltage U_{I}=Uₘₐₓ are determined. With the exception of battery cell m, all other battery cells in the cell block are then discharged via resistors connected in parallel with the battery cells until U_{I}=Uₘᵢₙ applies to the cell voltage Uᵢ of battery cell I. The method according to the invention is then repeated and all J battery cells are charged with the charging current I₀ until battery cell i is the first to reach its predetermined end-of-charge voltage U_{i,L} and the charging current is reduced to Iᵢ. Lowering the cell voltage of all battery cells ensures that all battery cells start with the same or similar cell voltages during subsequent charging. This process of charging and then discharging with the charging current turned off can be repeated several times. If necessary, this can be done at increasingly shorter intervals. With each cycle, the cell voltages of the cells move closer together. After several cycles the difference between the end-of-charge voltages of the individual cells becomes smaller and smaller. The process is terminated when the difference Uₘₐₓ−Uₘᵢₙ is less than or equal to a predefined limit Δ_{U1}. This limit can be, for example, 5 mV.

According to an advantageous embodiment of the invention, when the predetermined end-of-charge voltage U_{iL} of the battery cell i is reached, the reduction of the charging current to Iᵢ during the charging of the rechargeable energy storage switches from constant current, also referred to as constant current CC, to constant cell voltage of the battery cell i, also referred to as constant cell voltage CCV. In contrast to known charging methods, it is therefore important to reach the end-of-charge voltage of a battery cell instead of the block end-of-charge voltage, and when this goal is reached, the block voltage is not set to constant voltage CV, but only the cell voltage of the battery cell that has already reached its predetermined end-of-charge voltage. All other battery cells continue to be charged.

According to a further advantageous embodiment of the invention, for the predetermined voltage value Δ_{U1} the following applies: 0.01 U_{n,L}≤ΔU₁≤0.02*U_{n,L} where U_{n,L} is the predetermined end-of-charge voltage of at least one of the J battery cells.

According to a further advantageous embodiment of the invention, for the predetermined voltage value Δ_{U1} the following applies: 5 mV≤ΔU₁≤10 mV.

According to a further advantageous embodiment of the invention, the predetermined end-of-charge voltage U_{n,L} is the same for all J battery cells, and the following applies U_{n,L}=Uₙ+1,L for 1≤n≤J−1 or in other words U_{1,L}=U_{2,L}=U_{3,L}= . . . =U_{J,L}.

According to a further advantageous embodiment of the invention, the charging current threshold value I_{SW} is the same for all battery cells.

According to a further advantageous embodiment of the invention, the reduced charging current I_{SW,n} is predetermined for each battery cell as a function of a maximum charging current I_{n,max} assigned to each battery cell, where the following applies to the reduced charging current I_{SW,n}: 0.01 I_{n, max}≤I_{SW,n}≤0.02 I_{n,max} with 1≤n≤J.

The maximum charging current I_{n;max} of a battery cell is determined taking into account a predetermined C-factor. The C-factor is the quotient of the maximum charging current I_{n;max} and the capacity Cₙ of the battery cell in question. The maximum charging current of a battery cell and the C-factor are determined, for example, by a monitoring and control device.

According to a further advantageous embodiment of the invention, the reduced charging current Iₙ for each battery cell is between 1% and 2% of the charging current I₀, and the following applies 0.01 I₀≤Iₙ≤0.02 I₀. The reduced charging current Iₙ can be the same for all battery cells. Alternatively, the reduced charging current may be different.

According to a further advantageous embodiment of the invention, the capacity Cₙ for all J battery cells is determined after the cell block has been charged to be 1≤n≤J. Initially, all J battery cells have the same end-of-charge voltage, taking into account the tolerance Δ_{U1}. The end-of-charge voltage of all battery cells is either equal to their predetermined end-of-charge voltage U_{n,L} or differs from it by a maximum of ΔU₁, and the following applies U_{n,L}-ΔU₁≤Uₙ≤U_{n,L}. Starting from this end-of-charge voltage of the battery cells, all J battery cells are discharged with the discharging current I_{0′}. As soon as a battery cell p with 1≤p≤J reaches its specified end-of-discharge voltage U_{p,E}, the discharge of all battery cells is stopped and the time t_{E} from the start of the discharge to the end of the discharge is determined. The cell voltage Uₙ is then determined for each battery cell with 1≤n≤J at time t_{E}. For the battery cell p which was the first to reach its predetermined end-of-discharge voltage U_{p,E}, the time t_{E}, the discharging current I_{0′}, the end-of-charge voltage U_{p,L}, the cell voltage Up=U_{p,E} and the capacity Cₚ is determined. For the battery cell p, the cell voltage between the start of discharge and the end of discharge is given as a voltage-time curve as a function of time. On this voltage-time curve of the battery cell p, the times tₙ are assigned to the cell voltages Uₙ; which the battery cells have at the time t_{E}. From the times tₙ and the capacity Cₚ, the capacity Cₙ of all remaining J−1 battery cells is determined, which they will have when they reach their predetermined end-of-discharge voltage.

According to another advantageous embodiment of the invention, the cell voltage is recorded as a function of time for all battery cells during discharge. For all battery cells, the cell voltage as a function of time is stored as a voltage-time curve.

According to a further advantageous embodiment of the invention, the capacity Cₙ of the J battery cells is determined at specific time intervals and stored in a memory. It is thus available for comparisons or for determining the aging state of the battery cells and can be retrieved as required.

According to a further advantageous embodiment of the invention, the initial capacity C_{n,initial} for each battery cell is predetermined as 1≤n≤J, where the initial capacity C_{n,initial} is the capacity that the battery cell has before the initial commissioning. For each battery cell, the state of health SoH of the battery cell is determined at specific time intervals from the capacity Cₙ and the initial capacity C_{n,initial} using the following equation SoH=Cₙ/C_{n,initial}*100. The initial capacity C_{n,initial} can be determined by the method according to the invention directly during the initial commissioning of the cell block or by another method, or it can be predetermined by a manufacturer. The aging state of the battery cells can thus be determined at specific intervals or on specific request and is thus available at any time. The SoH state of the battery cells can be stored in a memory so that it can be retrieved at any time.

Further advantages and advantageous embodiments of the invention are set forth in the following description, the drawing and the claims.

### BRIEF DESCRIPTION OF THE DRAWINGS

The invention is now described based on an advantageous embodiment with reference to drawing figures, wherein:

FIG. 1 shows a schematic diagram of a rechargeable energy storage;

FIG. 2 shows cell voltage as a function of time for three battery cells of the cell block of the rechargeable energy storage according to FIG. 1; and

FIG. 3 shows voltage-time diagram of the battery cells of a rechargeable energy storage different from FIG. 1.

### DETAILED DESCRIPTION

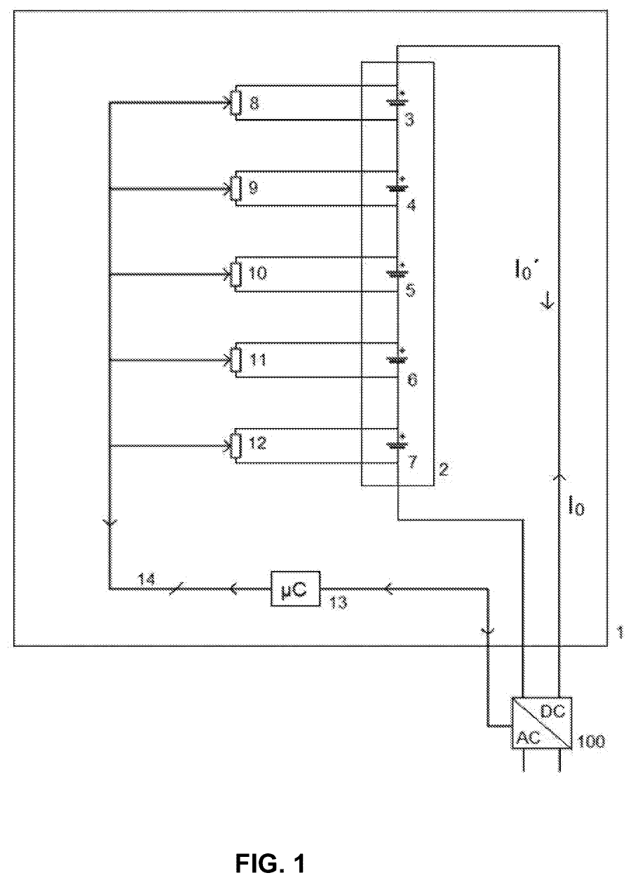

FIG. 1 shows a circuit diagram of a rechargeable energy storage 1 which is used, for example, to supply energy to the supply network of a building and which can be charged and discharged by a system for generating renewable energy (photovoltaic system, wind power system, biogas system, etc.), for example via a bidirectional AC/DC converter 100. In the embodiment shown, the rechargeable energy storage 1 comprises a cell block 2 with five rechargeable battery cells 3, 4, 5, 6, 7 connected in series. The number J of battery cells is therefore 5: J=5.

The battery cell with n=1 has the reference number 3, the battery cell with n=2 has the reference number 4, the battery cell with n=3 has the reference number 5, the battery cell with n=4 has the reference number 6, and the battery cell with n=5 has the reference number 7.

Each of the battery cells 3 to 7 is provided with a switchable resistor 8, 9, 10, 11, 12. The resistor 8 of battery cell 3 is connected in parallel. The same applies to resistors 9, 10, 11, 12 and battery cells 4, 5, 6, 7. Switchable means that the resistors are connected in parallel with the battery cells for a limited period of time during charging or discharging of the cell block.

A control and memory device 13 is provided for monitoring the charge or discharge status of the individual battery cells 3 to 7, which is connected via corresponding data lines 14 both to the switchable resistors 8 to 12 and to the bidirectional AC/DC converter 100.

The charging of cell block 2 is described below:

All battery cells 3 to 7 in the cell block 2 are initially charged with the charging current I₀. The cell voltage of the battery cells is continuously recorded. For each battery cell, the recorded cell voltage Uₙ is compared with the predetermined end-of-charge voltage U_{n,L} of this battery cell. The predetermined end-of-charge voltage U_{n,L} is the same for all battery cells 3 to 7 and is 4.2 V. The following applies: U_{1,L}=U_{2,L}=U_{3,L}=U_{4,L}=U_{5,L}=4.2 V. Charging of all battery cells with the charging current I₀ will continue until one of the battery cells 3 to 7 is the first to reach its predetermined end-of-charge voltage. In this example this is the cell with n=2 and reference number 4. The first cell i to reach its predetermined end-of-charge voltage is therefore cell 4 and i=2. The charging current is now reduced to 12, where 0 A<12<I₀. Then, all cells 3 through 7 are charged with the charging current 12 until the next cell reaches its predetermined end-of-charge voltage. In this example, this is the cell with n=1 and reference number 3. Battery cell j, the second to reach its predetermined end-of-charge voltage, is battery cell 3. The charging current is now reduced to I₁, where 0A<11<<12<I₀.

When the cell voltages Uₙ are recorded and the cell voltages Uₙ are compared with the predetermined end-of-charge voltages U_{n,L} of the battery cells, it is found that the remaining battery cells with reference numbers 5, 6, 7 already have a cell voltage which differs from their predetermined end-of-charge voltage by a maximum tolerance of ΔU₁=5 mV. Charging is terminated. The block end-of-charge voltage of the cell block is 5*4.2 V=21 V. This is also true taking into account the tolerance ΔU₁=5 mV for the end-of-charge voltage of each of the battery cells.

If it is determined that the reduced charging current I₁ is less than a predetermined charging current threshold value I_{SW}, the charging current is turned off. The battery cell with the lowest cell voltage is then determined. In this case it is cell 6 with n=4. The battery cell with the highest cell voltage is also determined. In this case it is cell 4 with n=2. The following applies: U₄<U₅<U₃<U₁<U₂.

Then, battery cells 3, 4, 5 and 7 are discharged with the charging current switched off via the switchable resistors 8, 9, 10, 12 assigned to them, until their cell voltage is equal to the cell voltage U₄. The charging process is then repeated with I₀ as described above. Since all the battery cells now start with the same cell voltage when charging is resumed, it is assumed that the predetermined end-of-charge voltages have been reached, as described above.

The capacities Cₙ of cells 3 to 7 are determined as follows: First, cell block 2 is charged, with all battery cells 3 to 7 having their predetermined end-of-charge voltage Uₙ=4.2 V with 1≤n≤5. Cell block 2 is then discharged with the discharging current I_{0′}. The discharging current I_{0′} flows through the battery cells 3 to 7 connected in series. During the discharge, the cell voltage Uₙ of the battery cells 3 to 7 is determined continuously or at predetermined intervals and compared with the end-of-discharge voltage U_{n,E} predetermined for each of the battery cells. If it is determined that at least one of the battery cells 3 to 7 has reached its predetermined end-of-discharge voltage, the following occurs: the discharge of the cell block 2 is terminated so that no more discharging current flows, the time t_{E} elapsing from the start of the discharge to the end of the discharge is determined, the cell voltage Uₙ(t_{E}) which the battery cells 3 to 7 have at the time t_{E} is determined for each battery cell, the capacity C₃ of the battery cell 5 is determined from the time t_{E}, the discharging current I_{0′}, the end-of-charge voltage U_{3,L} of the battery cell 5 and the end-of-discharge voltage U₃(t_{E})=U_{3,E} for the battery cell 5 with n=3 which was the first to reach its predetermined end-of-discharge voltage, a voltage-time curve is generated for battery cell 5 with n=3 by plotting the cell voltage as a function of time during the discharge from t=0 sec to t=t_{E}, on this voltage-time curve, the cell voltages Uₙ(t_{E}) of all battery cells except battery cell 5 are assigned times tₙ, for which Uₙ(t_{E})=U₃(tₙ), the times tₙ and the capacity C₃ are used to determine the capacity for the battery cells 3, 4, 6, 7 which the battery cells 3, 4, 6, 7 will have when they reach their predetermined end-of-discharge voltage.

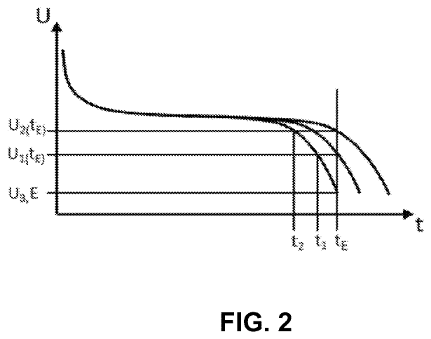

FIG. 2 shows the voltage-time curves Uₙ(t) of battery cells 3, 4 and 5 with n=1, 2 and 3, respectively, when cell block 2 is discharged with discharging current I_{0′}. The voltage-time curves of battery cells 6 and 7 with n=4 and n=5 are not shown for simplicity and clarity. Battery cell 5 with n=3 is the first to reach its predetermined end-of-discharge voltage U_{3,E} at time t=t_{E}. At this time battery cell 3 with n=1 has the cell voltage U₁(t_{E}) and battery cell 4 with n=2 has the cell voltage U₂(t_{E}), where U_{3,E}<U₁(t_{E})<U₂(t_{E}). The two battery cells 3, 4 with n=1 and n=2 have not yet reached their end-of-discharge voltages U_{1,E} and U_{2,E} at time t_{E}. Using the voltage-time curve U₃(t), the cell voltages U₁(t_{E}) and U₂(t_{E}) are assigned the times t₁ and t₂ so that U₁(t_{E})=U₃(t₁) and U₂(t_{E})=U₃(t₂).

The voltages U₃(t₁) and U₃(t₂), the times t₁, t₂ and t_{E} and the capacity C₃ already determined are then used to calculate the capacities C₁ and C₂ that the battery cells 3, 4 will have with n=1 and n=2 when their predetermined end-of-discharge voltage U_{1,E} and U_{2,E} is reached. It is assumed that the voltage-time curves of battery cells 3, 4 are qualitatively identical to the voltage-time curve of battery cell 5.

The capacities of battery cells 6, 7 are determined accordingly.

The capacities Cₙ determined in this way, where 1≤n≤5, are also referred to as useable capacities.

The capacities C₁, C₂, C₃, C₄ and C₅ are stored in a memory not shown in the drawing. Also stored in this memory are the capacities C_{n,initial}, which each of the five battery cells had before initial commissioning. This initial capacity is predetermined for each of the battery cells. Using the equation SoH=Cₙ/C_{n,initial}*100, the state of health SoH is determined and stored for each of the five battery cells.

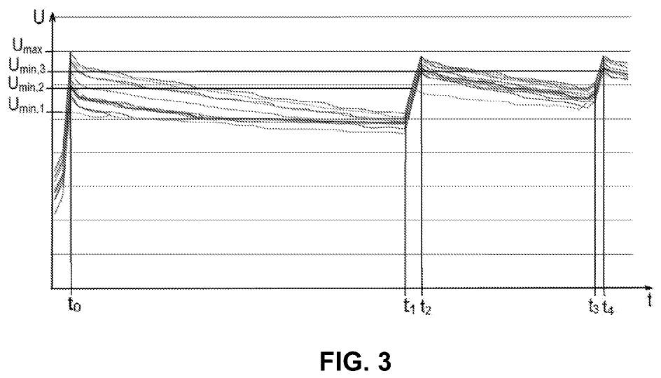

FIG. 3 shows two cycles of discharging and then recharging a cell block with several cells connected in series. The number of cells is greater than in cell block 2 in FIG. 1. However, the structure of the cell block is otherwise the same as cell block 2 in FIG. 1. The diagram in FIG. 3 plots the cell voltage U as a function of time t for each cell in the cell block. At time to, charging is completed in a first cycle and the charging current I₀ is turned off: I₀=0A. It is assumed that at least one cell has previously reached its predetermined end-of-charge voltage U_{n,L}, that the charging current has then been reduced at least once, and that the reduced charging current Iᵢ or Iᵢ is less than a predetermined charging current threshold. At time to, the cell m with the lowest cell voltage has voltage Uₘ=Uₘᵢₙ and the cell I with the highest cell voltage has voltage U_{I}=Uₘₐₓ. Since this is the lowest cell voltage in the first cycle, it is referred to as U_{min,1}. From time t₀, all the other cells except cell m are discharged through resistors connected in parallel with the cells when the charging current is turned off. The resistors connected in parallel with the cells are as shown in FIG. 1. The discharging of the cells lasts from to t₀ t₁. During this time t_{E} cell voltage of the cells decreases. Discharge is completed at time t₁ when the cell voltage of cell I is equal to U_{min,1}: U_{I}=U_{min,1}. At this time t_{E} cell voltage Uₙ of the cells is in a range Uₙ≤U_{min,1}. At time t₁, the charging current I₀ is switched on again and the cells are charged again until time t₂, at which time at least one cell has again reached its end-of-charge voltage, the charging current has been reduced at least once and the reduced charging current Iᵢ or Iⱼ is less than a predetermined charging current threshold value I_{SW}. The charging current is switched off again at time t₂. The first cycle, which lasts from to t₀ t₂, is completed. At time t₂, the cell with the lowest cell voltage has voltage U_{min,2}. This voltage is higher than the cell voltage V_{min,1} at the beginning of the first cycle. V_{min,2}>V_{min,1}. From time t₂ to time t₃ the cells are discharged, except for the cell with the lowest cell voltage, with the charging current switched off via the resistors connected in parallel, until time t₃ when the cell voltage of cell I is U_{min,2}: U_{I}=U_{min,2}. The charging current is then switched on again and the cells are charged again until time t₄. At time t₄ the cell with the lowest cell voltage has a voltage of U_{min,3}. This voltage is greater than the cell voltages V_{min,2} and V_{min,1} at the start of the first and second cycles. Uₘᵢₙ,3>Uₘᵢₙ,2>U_{min,1}. The second cycle is from t₂ to t₄. The diagram in FIG. 3 shows the cell voltage Uₘᵢₙ increases from cycle to cycle so that the difference between the end-of-charge voltage Uₘₐₓ of the cell with the highest cell voltage and Uₘᵢₙ becomes smaller and smaller. The repetition of cycles can be terminated when the cell voltages Uₘₐₓ and Uₘᵢₙ differ by less than a predetermined value in a cycle. The duration of the cycles becomes shorter as Uₘᵢₙ increases.

Although several embodiments of the present invention and its advantages have been described in detail, it should be understood that changes, substitutions, transformations, modifications, variations, permutations and alterations may be made therein without departing from the teachings of the present invention, the spirit and the scope of the invention being set forth by the appended claims.

### REFERENCE NUMERALS AND DESIGNATIONS

1 Rechargeable energy storage
2 Cell block
3 Battery cell
4 Battery cell
5 Battery cell
6 Battery cell
7 Battery cell
8 Switchable resistor
9 Switchable resistor
10 Switchable resistor
11 Switchable resistor
12 Switchable resistor
13 Control and memory device
14 Data line
100 Bidirectional AC/DC converter

What is claimed is:

1. A method for charging a rechargeable energy storage with a charging current, wherein the rechargeable energy storage includes at least one cell block including a number J of series-connected battery cells, wherein at least some of the battery cells have different capacities Cₙ, different internal resistances and/or different efficiencies, wherein 1≤n≤J, the method comprising:
a) charging all J battery cells with a charging current I₀;
b) recording cell voltage Uₙ of all J battery cells, wherein the recording is carried out continuously or at predetermined time intervals;
c) comparing the recorded cell voltage Uₙ of each battery cell with the predetermined end-of-charge voltage U_{n,L} specified for this battery cell;
d) as soon as a battery cell i with 1≤i≤J reaches a predetermined end-of-charge voltage U_{i,L} for this battery cell i, the charging current for all battery cells is reduced to a value Iᵢ where 0A<Iᵢ<I₀ whereby Iᵢ is a predetermined charging current for this battery cell i, at which the cell voltage Uᵢ of battery cell i does not rise above the end-of-charge voltage U_{i,L}, while all battery cells continue to be charged with the charging current Iᵢ;
e) as soon as during charging of the battery cells with the charging current Iᵢ, another battery cell j reaches its predetermined end-of-charge voltage, the charging current is further reduced to a charging current Iⱼ with 1≤j≤J and j≠i and Iⱼ<Iᵢ;
f) as soon as the reduced charging current Iᵢ or Iᵢ is less than a specified charging current threshold value I_{SW}, the charging current is switched off for all battery cells and the cell voltage Uₙ is determined for each battery cell with 1≤n≤J;
g) the battery cell m with the lowest cell voltage Uₘ=Uₘᵢₙ is determined and the battery cell I with the highest cell voltage U_{I}=Uₘₐₓ is determined; and
h) with exception of the battery cell m, all other battery cells are discharged via resistors which are connected in parallel with the battery cells until for the cell voltage U_{I} the following applies: U_{I}=Uₘᵢₙ,
wherein the steps a) to h) are repeated in cycles until the difference Uₘₐₓ−Uₘᵢₙ is less than or equal to a predetermined limit value Δ_{U1} and Uₘₐₓ−Uₘᵢₙ≤Δ_{U1} applies.

2. The method according to claim 1, wherein when the predetermined end-of-charge voltage U_{iL} of the battery cell i is reached through the reduction of the charging current to Iᵢ during charging of the rechargeable energy storage, a switchover from constant current to constant cell voltage of the battery cell i occurs.

3. The method according to claim 1, wherein the predetermined voltage value Δ_{U1} the following applies: 5 mV≤ΔU₁≤10 mV.

4. The method according to claim 1, wherein the predetermined end-of-charge voltage U_{n,L} is the same for all J battery cells and the following applies: U_{n,L}=Uₙ+1,L for 1≤n≤J−1.

5. The method according to claim 1, wherein the charging current threshold I_{SW} is the same for all battery cells.

6. The method according to claim 1, wherein each battery cell the charging current threshold value I_{SW,n} is predetermined as a function of a maximum charging current I_{n, max} assigned to each battery cell, and that for the charging current threshold value I_{SW,n} the following applies: 0.01 I_{n, max}≤I_{SW,n}≤0.02 I_{n,max} with 1≤n≤J.

7. The method according to claim 1, wherein each battery cell the reduced charging current Iₙ is between 1% and 2% of the charging current I₀ the following applies: 0.01 I₀≤Iₙ≤0.02 I₀.

8. The method according to claim 1, wherein all J battery cells after charging the cell block, all J battery cells having the same end-of-charge voltage U_{n,L}, the capacity Cₙ with 1≤n≤J is determined as follows:
all J battery cells are discharged with the discharge current I_{0′};
as soon as a battery cell p with 1≤p≤J reaches its specified end-of-discharge voltage U_{p,E}, the discharge of all battery cells is stopped and the time t_{E} from the start of discharge to the end of discharge is determined;
then the cell voltage Uₙ (t_{E}) is determined for each battery cell with 1≤n≤J at time t_{E},
for the battery cell p, which is the first to reach its specified end-of-discharge voltage U_{p,E}, the capacity Cₚ is determined from the time t_{E}, the discharge current I_{0′}, the end-of-charge voltage U_{p,L} and the cell voltage Up (t_{E})=U_{p,E},
for the battery cell p, the cell voltage between the start of discharge and the end of discharge is given as a voltage-time curve as a function of time,
on this voltage-time curve, the cell voltages Uₙ (t_{E}) of all battery cells are assigned times tₙ, for which Uₙ(t_{E})=Uₚ(tₙ) applies,
from the times tₙ and the capacity Cₚ, the capacity Cₙ of all the remaining J−1 battery cells is determined, which they have when their predetermined end-of-discharge voltage U_{n,E} is reached.

9. The method according to claim 8, wherein the cell voltage Uₙ of all J battery cells is recorded during discharge, whereby the recording is carried out continuously or at predetermined time intervals, and in that the recorded cell voltage Uₙ of each battery cell is compared with the predetermined end-of-discharge voltage U_{n,E} for this battery cell.

10. The method according to claim 8, wherein the cell voltage is recorded as a function of time for all battery cells during discharging, and in that the cell voltage is stored as a function of time as a voltage-time curve for all battery cells.

11. The method according to claim 9, wherein the cell voltage is recorded as a function of time for all battery cells during discharging, and in that the cell voltage is stored as a function of time as a voltage-time curve for all battery cells.

12. The method according to claim 8, wherein the capacity Cₙ of the J battery cells is determined at specific time intervals and is stored in a memory.

13. The method according to claim 9, wherein the capacity Cₙ of the J battery cells is determined at specific time intervals and is stored in a memory.

14. The method according to claim 10, wherein the capacity Cₙ of the J battery cells is determined at specific time intervals and is stored in a memory.

15. The method according to claim 11, wherein the capacity Cₙ of the J battery cells is determined at specific time intervals and is stored in a memory.

16. The method according to claim 8, wherein the for each battery cell its initial capacity C_{n,initial} is predetermined as 1≤n≤J, whereby the initial capacity C_{n,initial} is the capacity which the battery cell has before initial commissioning, and that for each battery cell the state of health SoH of the battery cell is determined at specific time intervals from the capacity Cₙ and the initial capacity C_{n,initial} with SoH=Cₙ/C_{n,initial}*100.

17. The method according to claim 9, wherein the for each battery cell its initial capacity C_{n,initial} is predetermined as 1≤n≤J, whereby the initial capacity C_{n,initial} is the capacity which the battery cell has before initial commissioning, and that for each battery cell the state of health SoH of the battery cell is determined at specific time intervals from the capacity Cₙ and the initial capacity C_{n,initial} with SoH=Cₙ/C_{n,initial}*100.

18. The method according to claim 10, wherein the for each battery cell its initial capacity C_{n,initial} is predetermined as 1≤n≤J, whereby the initial capacity C_{n,initial} is the capacity which the battery cell has before initial commissioning, and that for each battery cell the state of health SoH of the battery cell is determined at specific time intervals from the capacity Cₙ and the initial capacity C_{n,initial} with SoH=Cₙ/C_{n,initial}*100.

19. The method according to claim 11, wherein the for each battery cell its initial capacity C_{n,initial} is predetermined as 1≤n≤J, whereby the initial capacity C_{n,initial} is the capacity which the battery cell has before initial commissioning, and that for each battery cell the state of health SoH of the battery cell is determined at specific time intervals from the capacity Cₙ and the initial capacity C_{n,initial} with SoH=Cₙ/C_{n,initial}*100.

20. The method according to claim 12, wherein the for each battery cell its initial capacity C_{n,initial} is predetermined as 1≤n≤J, whereby the initial capacity C_{n,initial} is the capacity which the battery cell has before initial commissioning, and that for each battery cell the state of health SoH of the battery cell is determined at specific time intervals from the capacity Cₙ and the initial capacity C_{n,initial} with SoH=Cₙ/C_{n,initial}*100.
